(19) United States
(12) Patent Application Publication
(10) Pub. No.: US 2015/0276615 A1
(43) Pub. Date: Oct. 1, 2015

(54) OPTICAL SENSOR

(71) Applicant: DENSO CORPORATION, Aichi (JP)

(72) Inventors: Makiko Sugiura, Hekinan-city (JP); Kiyoshi Otsuka, Ichinomiya-city (JP); Tomohide Ariki, Anjo-city (JP)

(21) Appl. No.: 14/437,877

(22) PCT Filed: Nov. 28, 2013
(86) PCT No.: PCT/JP2013/007010

§ 371 Date: Apr. 23, 2015

(30) Foreign Application Priority Data
Dec. 4, 2012 (JP) 2012-265552
Sep. 9, 2013 (JP) 2013-186522

(51) Int. Cl. G01N 21/88; B60S 1/08; H01L 31/12; G01N 13/00; G01N 21/17

(52) U.S. Cl. CPC G01N 21/88; G01N 13/00; G01N 21/17; H01L 31/12; B60S 1/0833

(57) ABSTRACT

An optical sensor is attached to a transparent board and includes: a light emitting element that applies light to the transparent board; a plurality of light receiving elements that receive light from the light emitting element, reflected by the transparent board; and a detection unit that detects the amount of rainfall based on output signals of the light receiving elements. The light emitting element applies light to one irradiation region in the transparent board. The light receiving elements correspond to the one irradiation region and the detection unit detects the amount of rainfall based on output signals of the light receiving elements corresponding to the one irradiation region.

### CROSS REFERENCE TO RELATED APPLICATIONS

The present disclosure is based on Japanese Patent Applications No. 2012-265552 filed on Dec. 4, 2012, and No. 2013-186522 filed on Sep. 9, 2013, the disclosures of which are incorporated herein by reference.

### TECHNICAL FIELD

The present disclosure relates to an optical sensor including a light emitting element that applies light to a transparent board and a light receiving element that receives the light reflected by the transparent board.

### BACKGROUND ART

Patent Literature 1 describes a conventional raindrop detector, which includes a light emitting element that applies light to an inner surface of a windshield and a light receiving element that measures light reflected via the windshield. The detector detects the quantity of raindrops adhering to an outer surface of the windshield based on the amount of light received by the light receiving element.

Further, Patent Literature 2 describes a conventional vehicle-mounted rain sensor. This sensor includes: a light emitting part that applies light to a glass surface of a vehicle; a light detecting part that detects light reflected by the glass surface and outputs a detection signal corresponding to the detected light; and a signal processing part that determines rainfall based on the detection signal. The signal processing part calculates a light amount ratio, which is a ratio of a detection signal to a reference signal, and compares the result of the calculation with a light amount ratio under a clear sky, to determine the presence or absence of rainfall and the quantity of the rainfall.

### PRIOR ART LITERATURES

### Patent Literature

Patent Literature 1: JP 2006-071491 A (US 2006-043322 A1)

Patent Literature 2: JP 2007-240186 A

### SUMMARY OF INVENTION

Light is applied from the light emitting element to the inner surface of the windshield. If the irradiation region of light is widened in an attempt to widen the detection range of raindrops, the intensity of light in the irradiation region would be reduced as a whole. This may lead to reduction in the light intensity arising from the raindrops hitting the region.

The raindrop detector in Patent Literature 1 includes one light receiving element for one light emitting element; one light receiving element thus corresponds to one irradiation region. Widening the irradiation region of light may degrade the accuracy of raindrop detection.

It is thus a first object of the present disclosure to provide an optical sensor that suppresses degradation in the accuracy of raindrop detection.

In contrast, the vehicle-mounted rain sensor in Patent Literature 2 may include a plurality of detected light detecting parts, of which detection sensitivities may be individually adjusted. This case may lead to a configuration that adjusts individually the amount of light from the light emitting part (amount of light emission) according to each light detecting part. This may need to adjust the amount of light emission one by one by the number of the light detecting parts to thereby take time in adjusting detection sensitivity (the voltage level of the detection signal).

It is thus a second object of the present disclosure to provide an optical sensor that obtains a detection signal (electrical signal) of a desired voltage level in a short time.

To achieve the first object, according to a first example of the present disclosure, an optical sensor attached to a transparent board is provided to include a light emitting element, a plurality of light receiving elements, and a detection unit. The light emitting element applies light to the transparent board that reflects the light. The plurality of light receiving elements receive the light reflected by the transparent board. The detection unit detects an amount of rainfall based on output signals of the plurality of light receiving elements. Herein, the light emitting element applies light to a single irradiation region in the transparent board; the plurality of light receiving elements correspond to the single irradiation region; and the detection unit detects the amount of rainfall based on output signals of the plurality of light receiving elements corresponding to the single irradiation region.

This structure provides a plurality of light receiving elements that correspond to one irradiation region. This suppresses degradation in the accuracy of detection of raindrops detected at one light receiving element even when the irradiation region of light is widened, unlike a configuration providing one light receiving element that corresponds to one irradiation region.

The first example detects an amount of rainfall based on the output signals from the plurality of light receiving elements corresponding to one irradiation region, while suppressing degradation in the accuracy of detection of raindrops detected at one light receiving element. This suppresses degradation in the detection of the amount of rainfall, as compared with a configuration providing one light receiving element that corresponds to one irradiation region.

In the first example, the detection unit may include a weighting portion that adds a weight to output signals of the plurality of light receiving elements. The weight corresponds to a distribution of intensity of light incident on each of the plurality of light receiving elements. This enables the plurality of light receiving elements to provide respective detection sensitivities to be close to one another in a state where no deposit is on the transparent board.

Since light emitted from the light emitting element has an intensity distribution, light reflected at the irradiation region and incident on the light receiving elements also has an intensity distribution. Weighting each light receiving element depending on the intensity distribution of light may bring the respective detection sensitivities of the light receiving elements close to one another. This suppresses degradation in the accuracy of detection of the amount of rainfall due to variation in detection sensitivity from one light receiving element to another.

In the above configuration, the weighting portion may add the weight to an output signal of a light receiving element low in intensity of incident light among the plurality of light receiving elements, to cause an intensity of the output signal of the light receiving element low in intensity of incident light to be close to an intensity of an output signal of a light receiving element high in intensity of incident light.

As mentioned, light incident on the light receiving elements exhibits an intensity distribution. An output signal of a light receiving element high in the intensity of incident light is higher in intensity (voltage level) than an output signal of a light receiving element low in the intensity of incident light. The output signal of the light receiving element low in the intensity of incident light is weighted so as to be close, in the voltage level, to the output signal of the light receiving element high in the intensity of incident light. This can reduce any difference in detection sensitivity between the light receiving elements due to a difference in the intensity of incident light. This suppresses degradation in the accuracy of detection of the amount of rainfall due to variation in detection sensitivity from one light receiving element to another. This further enhances the detection sensitivity of the light receiving element low in the intensity of incident light, thereby enabling to detect a small quantity of raindrops adhering to the transparent board; such a small quantity of raindrops cannot be detected without weighting. Raindrops can be thus detected in the entire irradiation region; a detection range is widened.

Further, in the above configuration, the weighting portion may add the weight to each of the output signals of the plurality of light receiving elements to cause the output signals of the plurality of light receiving elements to provide respective intensities to be identical with one another.

The plurality of light receiving elements thus become identical in detection sensitivity. This suppresses degradation in the accuracy of detection of the amount of rainfall due to variation in detection sensitivity from one light receiving element to another.

The detection unit may include a comparison portion, a count portion, and a rainfall amount detection portion. The comparison portion compares each of the output signals of the plurality of light receiving elements weighted by the weighting portion with a threshold voltage and outputs a first signal when the output signal is lower than the threshold voltage and a second signal when the output signal is not lower than the threshold voltage. The count portion counts a counted number of either the first signal or the second signal outputted from the comparison portion. The rainfall amount detection portion detects an amount of rainfall based on the counted number that is counted by the count portion.

As mentioned, degradation is already suppressed in the accuracy of detection of raindrops detected at one light receiving element. Detecting the amount of rainfall depending on the number of first signals or second signals based on the output signals of the light receiving elements can therefore suppress degradation in the accuracy of detection of the amount of rainfall.

The comparison portion may include a plurality of the threshold voltages different in value as the threshold voltage and output the first signal or the second signal resulting from sequential comparison of the different threshold voltages with each of the output signals of the plurality of light receiving elements to the count portion. The rainfall amount detection portion may detect the amount of rainfall based on the counted number corresponding to each of the threshold voltages different in value.

This enables to detect the amount of rainfall more closely, as compared with a configuration including the comparison portion using one threshold voltage.

Further, to achieve the second object, according to a second embodiment of the present disclosure, an optical sensor is provided to include a light emitting element, a plurality of light receiving elements, and a voltage regulating portion. The light emitting element applies light to a transparent board (290) that reflects the light. The plurality of light receiving elements receive the light reflected by the transparent board, and convert the received light into electrical signals. The voltage regulating portion regulates a voltage level of the electrical signal outputted from each of the light receiving elements. Herein, each of the light receiving elements converts light into an electric charge and outputs a voltage corresponding to the electric charge as the electrical signal. The voltage regulating portion individually regulates an amount of the electric charge converted at each of the light receiving elements and individually adjusts the voltage level of the electrical signal of each of the light receiving elements.

This structure permits the voltage regulating portion to individually adjust both (i) the amounts of electric charges converted at the light receiving elements, and (ii) the voltage levels of the electrical signals of the light receiving elements. Thus an electrical signal of a desired voltage level can be obtained from each light receiving element just by requiring the light emitting element to emit light once, unlike in a comparative configuration that adjusts individually the amount of light emission of the light emitting element one by one in correspondence with each light receiving element to obtain an electrical signal of a desired voltage level from each light receiving element. Thus a desired electrical signal can be obtained in a short time as compared with the comparative configuration. When any deposit adhering to the transparent board is detected based on increase/decrease of electrical signals, the electrical signal of each light receiving element adjusted to a desired voltage level can be obtained just by causing the light emitting element to emit light once, unlike in the comparative configuration.

Further, the voltage regulating portion may include a switch that discharges electric charge accumulated in each of the light receiving elements, and a control unit that controls drive of the switch. The control unit may individually adjust driven time and non-driven time of the switch corresponding to each of the light receiving elements, to cause the voltage levels of the respective electrical signals of the light receiving elements to be identical with one another under states where no deposit adheres to the transparent board.

Since light projected from the light emitting element has directional characteristics, light reflected by the transparent board and incident on each light receiving element varies in amount. This causes the light receiving elements to be different in detection sensitivity from one another. The control unit is thus provided to individually adjust driven times and non-driven times of the switches to permit the light receiving elements to become identical in detection sensitivity. This suppresses variation in the quantity of electric charge converted at each light receiving element and suppresses variation in detection sensitivity from one light receiving element to another. This enhances the detection sensitivity for any deposit adhering to the transparent board when the deposit is detected based on increase/decrease of the electrical signals of the light receiving elements.

### BRIEF DESCRIPTION OF DRAWINGS

The above and other objects, features and advantages of the present disclosure will become more apparent from the following detailed description made with reference to the accompanying drawings. In the drawings:

FIG. 1 is a top view illustrating a schematic configuration of a rain sensor in a first embodiment of the present disclosure;

FIG. 2 is a sectional view showing a schematic configuration of a rain sensor;

FIG. 3 is a conceptional diagram illustrating an intensity distribution of reflected light and an arrangement of light receiving elements;

FIG. 4 is a conceptional diagram illustrating detection sensitivities of light receiving elements weighted by a weighting portion;

FIG. 5 is a top view of a rain sensor illustrating a modification to the first embodiment;

FIG. 6 is a sectional view of the rain sensor shown in FIG. 5;

FIG. 7 is a sectional view illustrating a schematic configuration of an optical sensor in a second embodiment of the present disclosure and a positional relation between the optical sensor and a transparent board;

FIG. 8 is a block diagram illustrating a schematic configuration of an optical sensor;

FIG. 9 is a circuit diagram illustrating connections between light receiving elements and switches;

FIG. 10 is a timing chart of a light emission time of a light emitting element and photoelectric conversion times of light receiving elements;

FIG. 11 is a flowchart illustrating a process for detecting a deposit; and

FIG. 12 is a circuit diagram illustrating connections between light receiving elements and switches in a modification to the second embodiment.

### EMBODIMENTS FOR CARRYING OUT INVENTION

### First Embodiment

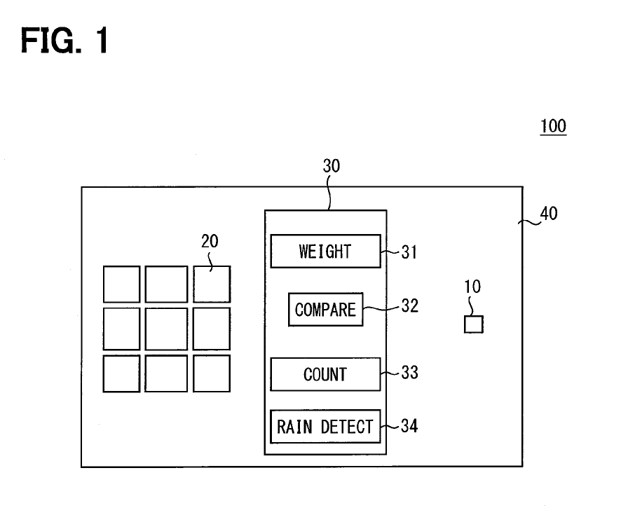

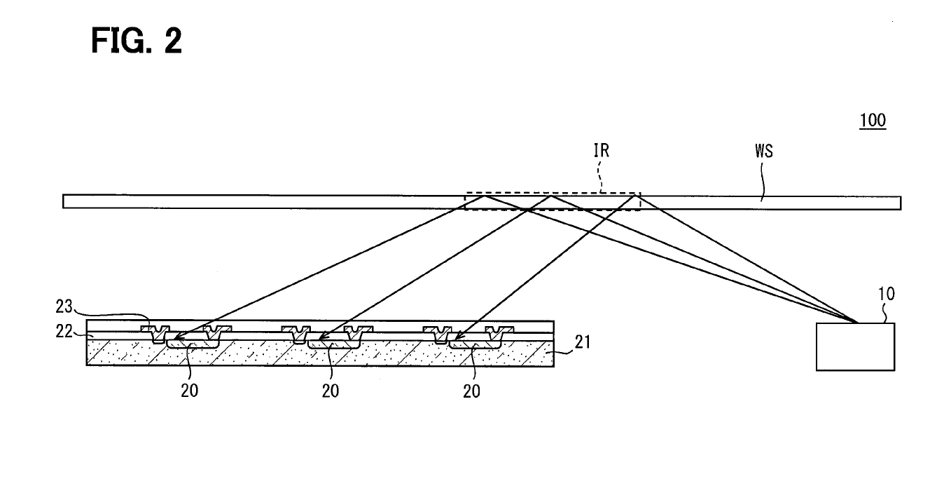

A description will be given to a rain sensor that functions as an optical sensor in a first embodiment with reference to FIG. 1 to FIG. 4. FIG. 2 omits a detection unit 30, to be described later.

The rain sensor 100, when used, is attached to the windshield WS of a vehicle. The windshield WS will be also referred to as a transparent board or a transparent substrate. The rain sensor 100 mainly includes a light emitting element 10, light receiving elements 20, and a detection unit 30. Light emitted from the light emitting element 10 is reflected by the windshield WS and the reflected light is incident on the light receiving elements 20. The light receiving elements 20 convert received light into electrical signals and output the resultant electrical signals to the detection unit 30. The detection unit 30 detects the quantity of raindrops adhering to the windshield WS, that is, the amount of rainfall based on the output signals of the light receiving elements 20.

With water adhering to the windshield WS, light incident on the water adherence area is not reflected in the interface between glass and water; thereby, the light passes through to the outside. This reduces the amount of light received at the light receiving element 20 and, further, the electrical signal of the light receiving element 20 inputted to the detection unit 30. This phenomenon permits the amount of rainfall to be detected based on reduction in the electrical signals of the light receiving elements 20. The present embodiment mounts the main elements 10 to 30 on a single substrate 40, which is attached to an inner surface of the windshield WS with an attaching portion (unshown).

The light emitting element 10 that is LED applies light to the inner surface of the windshield WS. One light emitting element 10 is provided in the single substrate 40. The light emitting element 10 functions to apply light to one area (irradiation region IR) encircled with a broken line in FIG. 2. In the embodiment, the light emitted from the light emitting element 10 is obliquely applied to the windshield WS to ensure the area of the irradiation region IR.

The light receiving element 20 receives light, which is emitted from the light emitting element 10 and reflected by the windshield WS. The light receiving element 20 is PD (Photo Diode); a plurality of light receiving elements 20 are provided in the single substrate 40. As in FIG. 2, the light receiving elements 20 correspond to the irradiation region IR, and in the embodiment, nine light receiving elements 20 correspond to the irradiation region IR. Each of the nine light receiving elements 20 functions to receive light reflected at the irradiation region IR (hereafter, referred to as reflected light).

As in FIG. 1, the nine light receiving elements 20 are arranged in a matrix of three rows and three columns. As in FIG. 2, a translucent film 22 and an impervious film 23 are laminated over a semiconductor substrate 21 where the light receiving elements 20 formed. The translucent film 22 allows reflected light to pass through and protects the light receiving elements 20. The impervious film 23 blocks reflected light and functions as an electrode of the light receiving elements 20.

The light emitted from the light emitting element 10 is thus obliquely applied to the windshield WS. To let reflected light enter the light receiving elements 20, the light emitting element 10 and the light receiving elements 20 are away from each other by a predetermined distance. Such distance produces a gap between the light emitting element 10 and the light receiving elements 20 that are placed over an identical substrate; the detection unit 30 may be placed in that gap.

The detection unit 30 detects the amount of rainfall based on output signals of the light receiving elements 20 corresponding to the irradiation region IR. As in FIG. 1, the detection unit 30 includes a weighting portion 31, a comparison portion 32, a count portion 33, and a rainfall amount detection portion 34; the unit 30 is placed between the light emitting element 10 and the light receiving elements 20.

The weighting portion 31 carries out weighting on the output signals of the light receiving elements 20. The comparison portion 32 compares each of the output signals of the light receiving elements 20 weighted by the weighting portion 31 with a threshold voltage Vth and outputs a first signal or a second signal. The count portion 33 counts the number of first signals or second signals outputted from the comparison portion 32. The rainfall amount detection portion 34 detects the amount of rainfall based on the result of counting by the count portion 33.

The weighting portion 31 adds a weight, which corresponds to the intensity distribution of incident light (reflected light) incident on each light receiving element 20, to the output signals of the light receiving elements 20. Adding the weight permits the respective detection sensitivities of the light receiving elements 20 to be close to one another under the state where any deposit is not on the windshield WS. Specifically, the weighting portion 31 carries out weighting on the output signals of light receiving elements 20 low in the intensity of reflected light. Thus without any deposit on the windshield WS, the output signals of the light receiving elements 20 are brought close to the intensity (voltage level) of the output signals of light receiving elements 20 high in the intensity of reflected light. More specifically, the weighting portion 31 carries out weighting on each of the output signals of the light receiving elements 20 corresponding to one irradiation region IR. Thus without any deposit on the windshield WS, the voltage levels of the output signals of the light receiving elements 20 are enabled to be identical with one another.

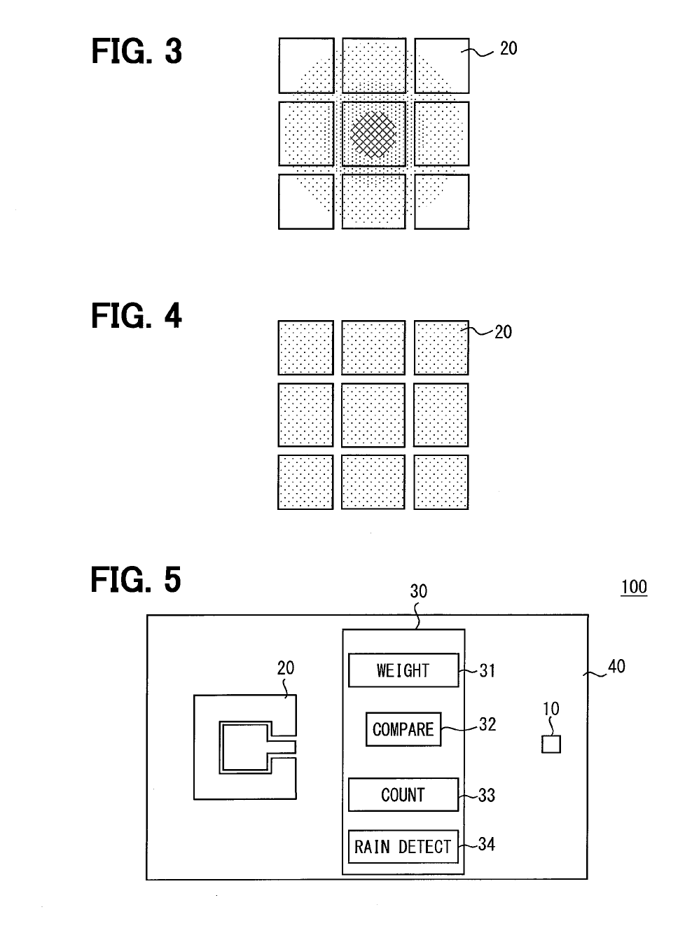

In FIG. 3, the intensity distribution of reflected light incident on each light receiving element 20 is indicated by dots. Denser dots indicate higher intensities of reflected light. In FIG. 3, the light receiving element 20 high in the intensity of reflected light is equivalent to the light receiving element 20 located in the second row and the second column; the light receiving elements 20 low in the intensity of reflected light are equivalent to the light receiving elements 20 located in the first row and the first column, the first row and the third column, the third row and the first column, and the third row and the third column. The weighting portion 31 carries out weighting so that the voltage levels of the output signals of the light receiving elements 20 become identical; thus, the voltage levels of the output signals of the light receiving elements 20 in three rows and three columns are adjusted approximately to correspond to the average intensity of reflected light incident on the nine light receiving elements 20. The adjusted voltage levels are substantially identical with the voltage levels of the output signals of the light receiving elements 20 in the first row and the second column, the second row and the first column, the second row and the third column, and the third row and the second column. The detection sensitivities of the light receiving elements 20 are therefore made uniform by the weighting portion 31 as indicated by the dots in FIG. 4. The weighting portion 31 is specifically an amplifier. The weight is equivalent to the amplification degree of the amplifier; one weighting portion 31 is provided for each light receiving element 20.

The comparison portion 32 compares each of the output signals of the light receiving elements 20 weighted by the weighting portions 31 with a threshold voltage Vth. The comparison portion 32 outputs a first signal when an output signal is lower than the threshold voltage Vth and outputs a second signal when an output signal is not lower than the threshold voltage Vth. Specifically, the comparison portion 32 is a comparator; the first signal is a Hi signal and the second signal is a Lo signal lower in voltage level than the Hi signal. Each light receiving element 20 and the comparison portion 32 electrically connected with each other through a corresponding weighting portion 31 and switch (unshown). The light receiving elements 20 and the comparison portion 32 are sequentially electrically connected with each other by changing switches. Thus, a Hi signal or a Lo signal is sequentially inputted from the comparison portion 32 to the rainfall amount detection portion 34 through the count portion 33.

The comparison portion 32 has a plurality of threshold voltages Vth different in value as the threshold voltage Vth. The comparison portion 32 compares some threshold voltage Vth with the respective output signals of the light receiving elements 20 and then changes the threshold voltage Vth. The comparison portion 32 compares a changed threshold voltage Vth with the respective output signals of the light receiving elements 20 and sequentially repeats this processing. Change of threshold voltages Vth is made at the rainfall amount detection portion 34 to be described later. Therefore, the Hi signals and Lo signals (the number of counts to be described later) of the comparison portion 32 corresponding to changed threshold voltages Vth are inputted to the rainfall amount detection portion 34.

The count portion 33 counts the number of Hi signals or Lo signals outputted from the comparison portion 32 and outputs a count signal containing the number of counts to the rainfall amount detection portion 34.

The rainfall amount detection portion 34 detects the amount of rainfall based on the threshold voltages Vth and the number of counts. As mentioned, the comparison portion 32 sequentially compares the threshold voltages Vth different in value with each of the output signals of the light receiving elements 20. Then the comparison portion 32 outputs a Hi signal when an output signal is lower than a threshold voltage Vth and outputs a Lo signal when an output signal is not lower than a threshold voltage Vth. In the following, a threshold value highest in voltage level among the threshold voltages Vth different in value will be taken as a first threshold voltage Vth1 for the explanation of detection of the amount of rainfall. The numbering will be increased as the voltage level is lowered.

First, the rainfall amount detection portion 34 receives the result of comparison of the first threshold voltage Vth1 with the respective output signals of the nine light receiving elements 20 as a count signal (number of counts) of the count portion 33. When there is no deposit on the windshield WS, the intensity of reflected light is highest; therefore, the voltage levels of the respective output signals of the nine light receiving elements 20 are also highest. Consequently, when the threshold voltage Vth is the first threshold voltage Vth1 and the number of counts of Hi signal is 0, the minimum value (the number of counts of Lo signal is 9, the maximum value), the determination below is made. The rainfall amount detection portion 34 determines that any raindrop does not adhere to the windshield WS and determines that the amount of rainfall is zero, that is, rain is not falling. When the threshold voltage Vth is the first threshold voltage Vth1 and the number of counts of Hi signal exceeds the number of counts of Lo signal, the determination below is made. The rainfall amount detection portion 34 determines that a raindrop adheres to the windshield WS and determines that rain is falling. The rainfall amount detection portion 34 determines that light rain is falling. The number of counts of Hi signal exceeding the number of counts of Lo signal signifies as follows. In a configuration including the count portion 33 counting Hi signals, the number of counts is 5 to 9 more than half; in a configuration including the count portion 33 counting Lo signals, the number of counts is 0 to 4 less than half.

When the threshold voltage is changed to a second threshold voltage Vth2 lower in voltage level than the first threshold voltage Vth1, the determination blow is made. When the number of counts of Hi signal exceeds the number of counts of Lo signal, the rainfall amount detection portion 34 determines that a raindrop adheres to the windshield WS and determines that ordinary rain is falling.

When the threshold voltage is changed to a third threshold voltage Vth3 lower in voltage level than the second threshold voltage Vth2, the determination below is made. When the number of counts of Hi signal exceeds the number of counts of Lo signal, the rainfall amount detection portion 34 determines that a raindrop adheres to the windshield WS and determines that heavy rain is falling.

An output signal expected to be outputted from a light receiving element 20 when a raindrop does not adhere to the windshield WS will be hereafter referred to as an expected signal. The first threshold voltage Vth1 has a value equal to 99% of the voltage level of the expected signal. The second threshold voltage Vth2 has a value equal to 95% of the voltage level of the expected signal; the third threshold voltage Vth3 has a value equal to 90% of the voltage level of the expected signal.

Therefore, the raindrop detection portion 34 determines that light rain is falling when raindrops adhering in the irradiation region IR of the windshield WS reduce the respective voltage levels of the output signals of five or more (or more than half of) light receiving elements 20 by not less than 1% and less than 5%. The raindrop detection portion 34 determines that ordinary rain is falling when raindrops adhering in the irradiation region IR of the windshield WS reduce the respective voltage levels of the output signals of five or more (or more than half of) light receiving elements 20 by not less than 5% and less than 10%. The raindrop detection portion 34 determines that heavy rain is falling when raindrops adhering in the irradiation region IR of the windshield WS reduce the respective voltage levels of the output signals of five or more (or more than half of) light receiving elements 20 by 10% or more.

As described, the rainfall amount detection portion 34 determines the presence or absence of a raindrop and the degree of the amount of rainfall based on the voltage levels of the threshold voltages Vth and the number of counts. When the rain sensor 100 is mounted in a vehicle as in the embodiment, the rainfall amount detection portion 34 also communicates a drive signal commanding driving of the wiper on the vehicle to the CPU of the vehicle. When the rainfall amount detection portion 34 determines that light rain is falling, the detection portion 34 outputs a first drive signal to the CPU; and when the detection portion 34 determines that ordinary rain is falling, the detection portion 34 outputs a second drive signal to the CPU. When the rainfall amount detection portion 34 determines that heavy rain is falling, the detection portion 34 outputs a third drive signal to the CPU. The first drive signal contains a command to operate the wiper at a first speed; the second drive signal contains a command to operate the wiper at a second speed faster than the first speed. The third drive signal contains a command to operate the wiper at a third speed faster than the second speed.

A description will be given to operational effects of the rain sensor 100 in the embodiment. As mentioned, the nine light receiving elements 20 correspond to one irradiation region IR. This suppresses degradation in the accuracy of detection of a raindrop detected by one light receiving element 20 even when the irradiation region IR of light is widened, unlike a configuration including one light receiving element that corresponds to one irradiation region.

The detection unit 30 detects the amount of rainfall based on the output signals of the nine light receiving elements 20 corresponding to one irradiation region IR. This suppresses degradation in the accuracy of detection of a raindrop detected by one light receiving element 20, further suppressing degradation in the accuracy of detection of the amount of rainfall, as compared with a configuration including one light receiving element that corresponds to one irradiation region.

Each weighting portion 31 adds a weight, which corresponds to the intensity distribution of reflected light incident on each of the light receiving elements 20, to the output signal of each light receiving element 20. Without any deposit on the windshield WS, the respective detection sensitivities of the light receiving elements 20 are thus brought close to one another.

As in FIG. 3, light (reflected light) incident on each light receiving element has an intensity distribution. Weighting corresponding to the intensity distribution is thus made at each of the light receiving elements 20 so that the respective detection sensitivities of the light receiving elements 20 are brought close to one another. This suppresses degradation in the accuracy of detection of the amount of rainfall due to variation in detection sensitivity from one light receiving element 20 to another.

In specific, the weighting portions 31 conducts weighting on the output signals of light receiving elements 20 low in the intensity of reflected light. Without any deposit on the windshield WS, the output signals are thus brought close to the voltage levels of the output signals of light receiving elements 20 high in the intensity of reflected light among the light receiving elements 20.

The reflected light incident on the light receiving elements 20 has an intensity distribution. The output signals of light receiving elements 20 high in the intensity of reflected light is therefore higher in voltage level than the output signals of light receiving elements 20 low in the intensity of reflected light. Weighting is thus conducted on the output signals of light receiving elements 20 low in the intensity of reflected light. Thus the output signals are brought close to the voltage levels of the output signals of light receiving elements 20 high in the intensity of reflected light. This can reduce any difference in detection sensitivity between light receiving elements 20 due to a difference in the intensity of reflected light. This suppresses degradation in the accuracy of detection of the amount of rainfall due to variation in detection sensitivity from one light receiving element 20 to another. The detection sensitivities of light receiving elements 20 low in the intensity of reflected light are enhanced. This can detect a small quantity of raindrops adhering to the windshield WS, which cannot be detected with weighting not being conducted. This widens a detection range.

In specific, each weighting portion 31 conducts weighting on each of the output signals of the light receiving elements 20. Without any deposit on the windshield WS, the voltage levels of the respective output signals of the light receiving elements 20 are thus made identical with one another. This makes the respective detection sensitivities of the light receiving elements 20 identical with one another. This suppresses degradation in the accuracy of detection of the amount of rainfall due to variation in detection sensitivity from one light receiving element 20 to another.

The detection unit 30 includes: the comparison portion 32 that compares each of the output signals of the light receiving elements 20 weighted by the weighting portions 31 with a threshold voltage Vth; the count portion 33 that counts the number of output signals of the comparison portion 32; and the rainfall amount detection portion 34 that detects the amount of rainfall based on the result of counting by the count portion 33.

As mentioned, degradation in the accuracy of detection of a raindrop detected at one light receiving element 20 is suppressed. Degradation in the accuracy of detection of the amount of rainfall is thus suppressed by detecting the amount of rainfall based on the number of Hi signals or Lo signals (the number of counts) based on the output signals of the light receiving elements 20.

The comparison portion 32 has a plurality of threshold voltages Vth different in value as the threshold voltage Vth. The comparison portion 32 compares some threshold voltage Vth with each of the output signals of the light receiving elements 20 and then changes the threshold voltage Vth. The comparison portion 32 compares a threshold voltage Vth with each of the output signals of the light receiving elements 20 again and repeats this processing. The rainfall amount detection portion 34 receives a Hi signal and a Lo signal (the number of counts) of the comparison portion 32 corresponding to a changed threshold voltage Vth. The rainfall amount detection portion 34 determines the presence or absence of raindrops and the degree of the amount of rainfall based on the voltage level of the threshold voltage Vth and the number of counts. This can detect the amount of rainfall more closely as compared with a configuration including the comparison portion having one threshold voltage.

The detection unit 30 is placed between the light emitting element 10 and the light receiving elements 20. Widening the irradiation region IR requires the light emitted from the light emitting element 10 to be obliquely applied to the windshield WS; this causes light emitted from the light emitting element 10 and reflected by the windshield to become oblique. To let light reflected by the windshield WS (reflected light) enter the light receiving elements 20, some distance is ensured between the light emitting element 10 and the light receiving elements 20 to produce an area as a dead space. Such an area is used to place the detection unit 30. This suppresses increase in the physical size of the rain sensor 100 as compared with a configuration including the detection unit 30 that is placed in an area other than the dead space.

The description has been given to a preferred embodiment of the present disclosure. The present disclosure is not limited to the embodiment and can be variously modified without departing from the subject matter of the present disclosure.

The present embodiment explained an example forming nine light receiving elements 20 in the substrate 21. The number of light receiving elements 20 is not limited to the example and only has to be more than one. As in FIG. 5, two is also acceptable as the number of light receiving elements 20.

Though not especially stated, the embodiment explained an example providing each of the nine light receiving elements 20 to have a planar shape being square as in FIG. 1. As in FIG. 5, the planar shape of light receiving elements 20 is not limited to the example. The arrangement and planar shape of light receiving elements 20 only have to be set according to the intensity distribution of light incident on the light receiving elements 20.

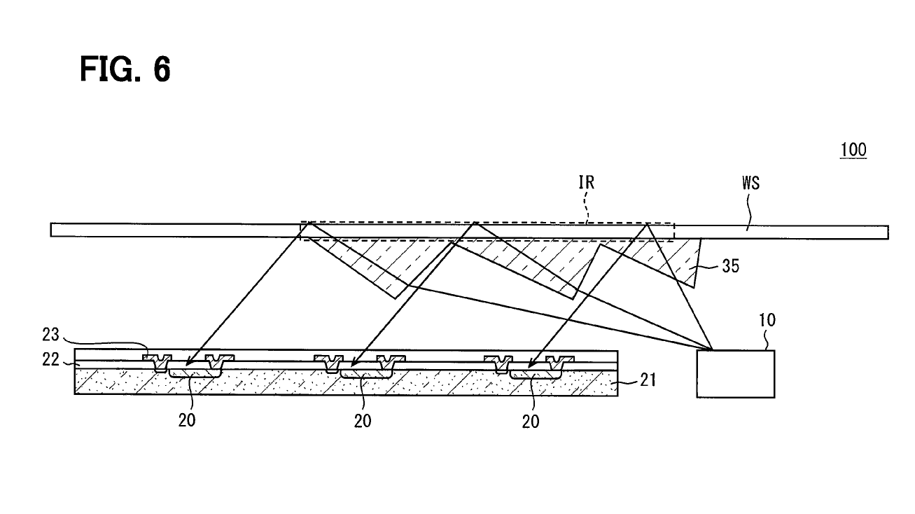

The present embodiment explained an example providing reflected light reflected by the windshield WS to be incident on the light receiving elements 20 through the translucent film 22 as in FIG. 1. Instead, the configuration illustrated in FIG. 6 may be adopted. That is, a rain sensor 100 is provided with a lens 35 to adjust the incident angle of light incident on the light receiving elements 20 and reflected light enters the light receiving elements 20 through this lens 35 and the translucent film 22. Unlike the embodiment, the configuration in FIG. 6 does not require the light emitting element 10 and the light receiving elements 20 to be away from each other by a predetermined distance to let reflected light enter the light receiving elements 20.

The present embodiment does not especially refer to the relation between the substrate 40 and the substrate 21. These substrates may be an identical member or may be different members.

The present embodiment explained an example providing each weighting portion 31 conducting weighting on each of the output signals of the light receiving elements 20. Without any deposit on the windshield WS, the respective voltage levels of the output signals of the light receiving elements 20 thus become identical with one another. Instead, a different configuration may be adopted which provides the weighting portions 31 carry out weighting on the output signals of light receiving elements 20 low in the intensity of reflected light. Without any deposit on the windshield WS, the output signals are thus brought close to the intensity (voltage level) of the output signals of light receiving elements 20 high in the intensity of reflected light among the light receiving elements 20. The weighting portions 31 only have to add a weight, which corresponds to the intensity distribution of incident light (reflected light) incident on each light receiving element 20, to the output signals of the light receiving elements 20. Without any deposit on the windshield WS, the respective detection sensitivities of the light receiving elements 20 are thus brought close to one another.

The present embodiment illustrates nine light receiving elements 20 in FIG. 1. The number of the light receiving elements may be two at minimum or more and may be several tens of thousands of pixels as in an imager at maximum.

The present embodiment explained an example in which the first signal is a Hi signal and the second signal is a Lo signal. Instead, the first signal may be a Lo signal and the second signal may be a Hi signal.

The present embodiment explained an example providing the comparison portion 32 to have a plurality of threshold voltages Vth different in value as the threshold voltage Vth. The comparison portion 32 only has to have at least one threshold voltage Vth. When the comparison portion 32 has only one threshold voltage Vth, the rainfall amount detection portion 34 determines the presence or absence of a raindrop and the degree of the amount of rainfall by only the number of counts.

The present embodiment explained an example in which the threshold values are defined as follows. The first threshold voltage Vth1 has a value equal to 99% of the voltage level of the expected signal; the second threshold voltage Vth2 has a value equal to 95% of the voltage level of the expected signal; and the third threshold voltage Vth3 has a value equal to 90% of the voltage level of the expected signal. This is just an example and the value of the threshold voltage Vth is not limited to the example.

### Second Embodiment

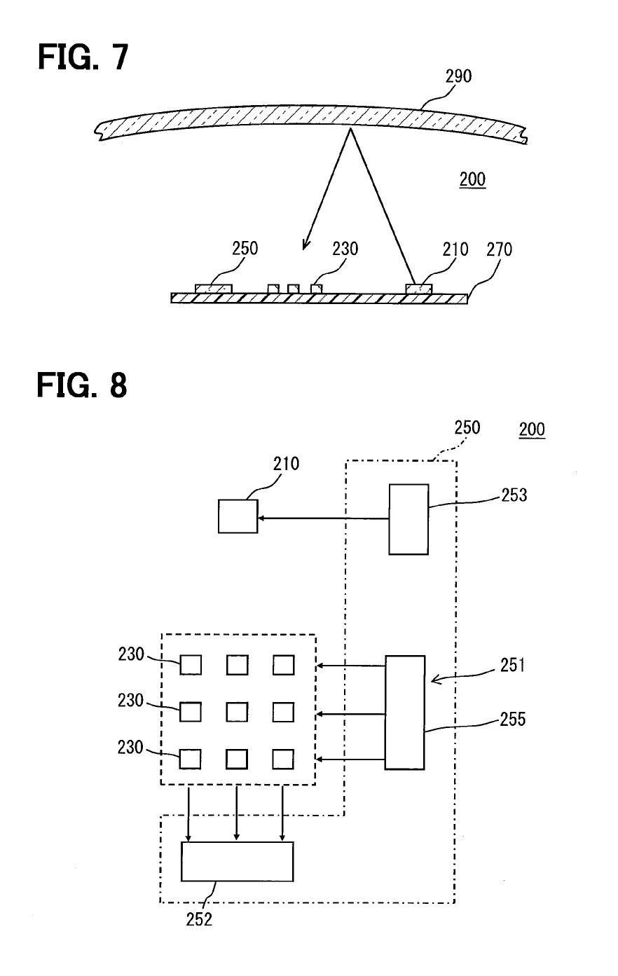

The following will describe an optical sensor in a second embodiment of the present disclosure with reference to FIGS. 7 to 11. In FIG. 8, a plurality of light receiving elements 230 are encircled with a broken line to show that the light receiving elements 230 are integrated in one area in a wiring board 270. The switches 254 and resistors 256 described later are located in the area encircled with the broken line. In FIG. 10, the horizontal axis indicates time; the value of each signal indicates a voltage level. A signal corresponding to a light emitting element 210 indicates the amount of current passed through the light emitting element 210 and the time of the energization. That is, the signal indicates (i) the amount of light emission and (ii) light emission time of the light emitting element 210. A signal corresponding to a light receiving element 230 indicates electric charges subjected to photoelectric conversion at the light receiving elements 230, that is, a voltage corresponding to the electric charges.

As in FIG. 7, the optical sensor 200 includes a light emitting element 210, light receiving elements 230, a circuit unit 250, and a wiring board 270. The light emitting element 210 applies light to a transparent board 290; and the light receiving elements 230 receive light from the light emitting element 210 reflected by the transparent board 290 and convert the light into electrical signals. As in FIG. 8, the circuit unit 250 includes a voltage regulating portion 251 and a processing portion 252. The voltage regulating portion 251 regulates the voltage level of the electrical signal outputted from each of a plurality of the light receiving elements 230; the processing portion 252 processes an electrical signal whose voltage level is regulated, outputted from each of the light receiving elements 230. In the embodiment, the circuit unit 250 also includes a light emission amount adjusting portion 253 that adjusts the amount of light emission from the light emitting element 210.

The light emitting element 210 applies light to the light receiving elements 230 through the transparent board 290. The light emitting element 210 in the embodiment is LED and one is provided in the wiring board 270. Therefore, light, which is projected from the one light emitting element 210 and then reflected by the transparent board 290, is incident on each of the light receiving elements 230. Light projected from the light emitting element 210 has an intensity distribution. Thus, even when any deposit does not adhere to the transparent board 290, reflected light has also an intensity distribution. There is a difference in the amount of light incident on the individual light receiving elements 230 for a predetermined time.

Each of the light receiving elements 230 converts light into electric charges and outputs a voltage corresponding to the electric charges as an electrical signal. The light receiving element 230 in the embodiment is PD (Photo Diode) and nine are provided in a matrix (three rows and three columns) in the wiring board 270. Reflected light is incident on each of the nine light receiving elements 230 but the amount of the incident light differs from one light receiving element 230 to another. However, the amounts of light incident on the light receiving elements 230 are apparently made equal and the electric charges (currents) outputted from the individual light receiving elements 230 are made equal. To do this, the driven time and non-driven time of the switch 254 corresponding to each of the light receiving elements 230 are individually adjusted as described later.

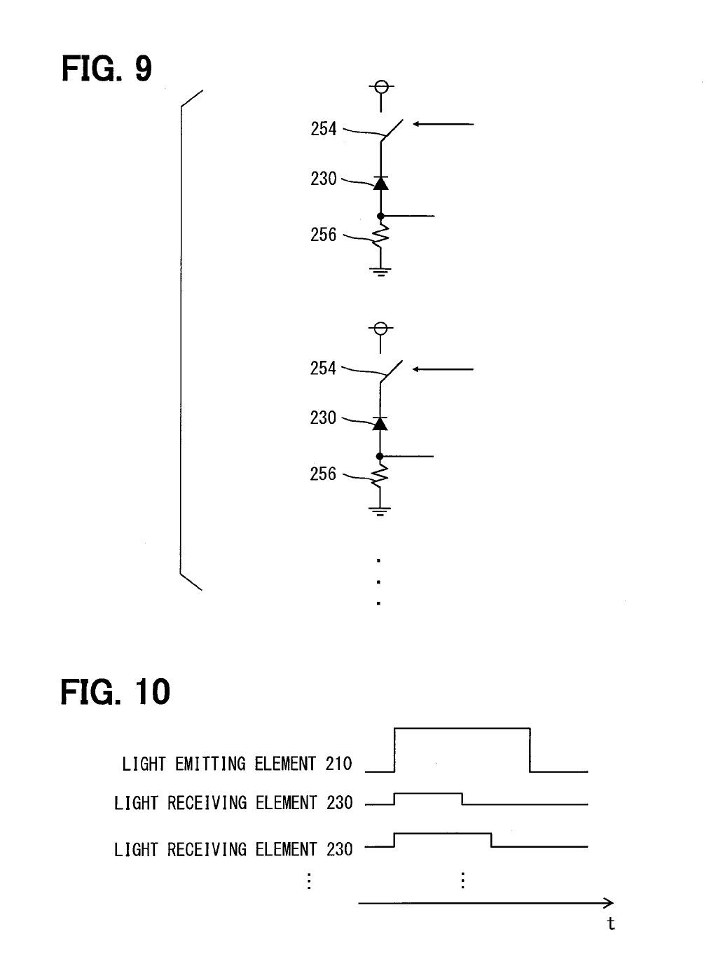

As mentioned, the circuit unit 250 includes the voltage regulating portion 251, the processing portion 252, and the light emission amount adjusting portion 253. The voltage regulating portion 251 individually adjusts the amount of the electric charges converted at the individual light receiving elements 230 and thereby individually adjusts the voltage level of the electrical signal of each light receiving element 230. The voltage regulating portion 251 includes: a plurality of switches 254 corresponding to the individual light receiving elements 230 and discharging electric charges accumulated in the light receiving elements 230; and a control portion 255 that controls the driving state of each switch 254. As in FIG. 9, a switch 254, a light receiving element 230, and a resistor 256 are connected in series in this order from a power supply to the ground. The midpoint potential between a light receiving element 230 and a resistor 256 provides the electrical signal (output signal) of the light receiving element 230. When a switch 254 is in a non-driving state, the midpoint potential varies according to the electric charges accumulated in the corresponding light receiving element 230. With increase in non-driven time, the amount of accumulated electric charges is increased and the midpoint potential is raised. When a switch 254 is in a driving state, meanwhile, the voltage across the corresponding light receiving element 230 is kept constant; therefore, the midpoint potential becomes constant regardless of the incidence of light on the light receiving element 230. As mentioned, the midpoint potential is determined by the driven time and non-driven time of a switch 254.

As in FIG. 10, the control portion 255 individually adjusts the driven time and non-driven time of a switch 254 corresponding to each light receiving element 230 with the light emitting element 210 emitting light. The control portion 255 thereby individually adjusts the amount of electric charges converted at each light receiving element 230 and individually adjusts the voltage levels of the respective electrical signals of the light receiving elements 230. In the embodiment, the control portion 255 individually adjusts the non-driven time of a switch 254 corresponding to each light receiving element 230. Thus without any deposit adhering to the transparent board 290, the voltage levels of the respective electrical signals of the light receiving elements 230 are made identical with one another. More specifically, without any deposit adhering to the transparent board 290, the voltage level of the electrical signal of each light receiving element 230 is made equal to the voltage level of an electrical signal that is expected to be outputted from one of the light receiving elements 230. (This signal will be hereafter referred to as an expected signal.)

The processing portion 252 detects any deposit adhering to the transparent board 290 based on increase/decrease of the electrical signal of each light receiving element 230. More specifically, the processing portion 252 determines that a deposit adheres to the transparent board 290 when an inspection value obtained by subtracting the voltage level of the electrical signal of each light receiving element 230 from the voltage level of the expected signal is greater than a threshold value. In the embodiment, the processing portion 252 determines that a deposit adheres to the transparent board 290 when the smallest inspection value of the inspection values corresponding to the individual light receiving elements 230 is greater than the threshold value.

The light emission amount adjusting portion 253 adjusts at least either of (i) the amount of current passed through the light emitting element 210 for a unit time and (ii) the time of the energization. The adjusting portion 253 thereby adjusts the amount of light emission from the light emitting element 210. By adjusting the amount of light emission, a desired electrical signal can be obtained from the light receiving elements 230 even when the surface of the transparent board 290 is uniformly dirty. Whether or not the surface of the transparent board 290 is uniformly dirty is determined based on whether or not the voltage levels of the respective electrical signals of the light receiving elements 230 are evenly lowered. This determination is made at the processing portion 252 and the result of determination is inputted to the light emission amount adjusting portion 253. The light emission amount adjusting portion 253 adjusts the amount of light emission from the light emitting element 210 according to the condition of the surface of the transparent board 290 inputted from the processing portion 252. Specifically, when the surface of the transparent board 290 is uniformly dirty, the amount of current passed through the light emitting element 210 for a unit time becomes larger than when the surface of the transparent board 290 is clean.

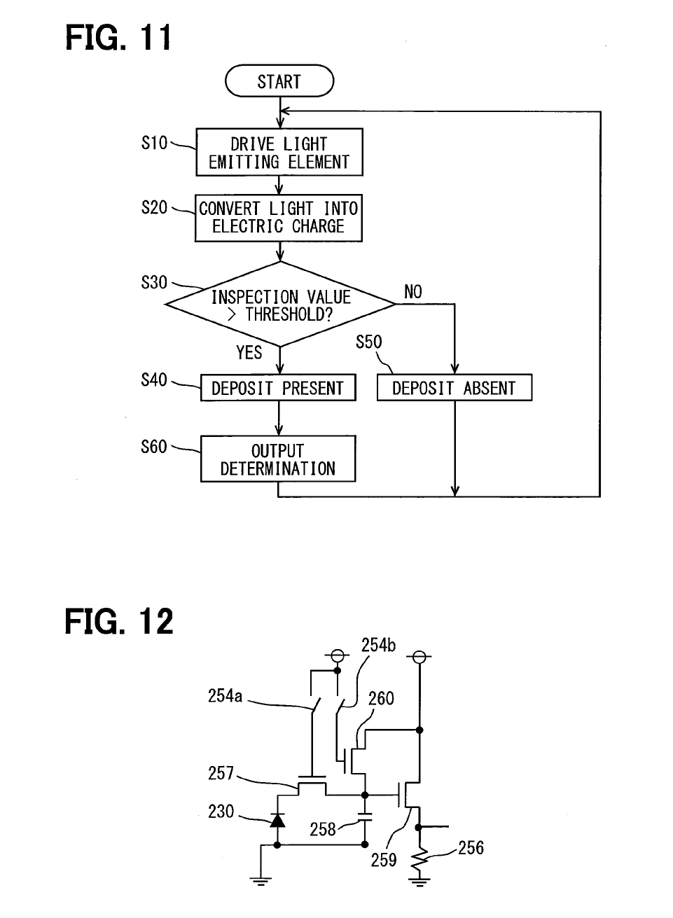

The following will describe the determination of any deposit with reference to FIG. 11. In the embodiment, the optical sensor 200 is mounted in a vehicle; the transparent board 290 is a windshield or a front windshield; the deposit is a raindrop. Before detecting any raindrop, a current is supplied to the light emitting element 210 by the light emission amount adjusting portion 253; light is thereby applied from the light emitting element 210 to the windshield 290 (Step S10). Light is thus incident on the windshield 290 and reflected light corresponding to the condition of the windshield 290 is incident on each of the light receiving elements 230. Each light receiving element 230 continuously converts the incident reflected light into electric charges during the non-driven time of a switch 254 corresponding to the light receiving element 230 (Step S20). The voltage based on the electric charges produced by this photoelectric conversion is inputted to the processing portion 252; the processing portion 252 makes the determination of any raindrop based on the input voltage (Step S30).

When a raindrop does not adhere to the outer surface of the windshield 290, almost all the light incident on the windshield 290 is reflected at the interface between the windshield 290 and air; the reflected light is incident on the light receiving elements 230. Meanwhile, when a raindrop adheres to the windshield 290, light passes through the windshield 290 to the outside because of the raindrop; the reflected light incident on the light receiving elements 230 is reduced. When the surface of the windshield 290 is not clean, the reflected light incident on the light receiving elements 230 is reduced. When the surface of the windshield 290 is clean and any raindrop does not adhere, it is expected that the expected signal is outputted from the light receiving elements 230. When the surface of the windshield 290 is not clean or a raindrop adheres to the surface, it is expected that an electrical signal whose voltage level is reduced and lower than the expected signal is outputted from the light receiving elements 230. The processing portion 252 holds the voltage level A of the expected signal and calculates an inspection value. This inspection value is obtained by subtracting the voltage level a of an electrical signal actually outputted from the light receiving elements 230 from the voltage level of the expected signal. The processing portion 252 holds a threshold value for determining whether or not a raindrop adheres and compares an inspection value with the threshold value. When an inspection value is larger than the threshold value, the processing portion 252 determines that a raindrop adheres to the windshield 290 (Step S40). When an inspection value is not larger than the threshold value, the processing portion 252 determines that any raindrop does not adhere to the windshield 290 (Step S50). As mentioned, when the smallest one of the inspection values corresponding to the individual light receiving elements 230 is larger than the threshold value, the processing portion 252 determines that a raindrop adheres to the windshield 290.

When the processing portion 252 determines that a raindrop adheres, the processing portion 252 outputs a determination signal to a control circuit controlling the wiper mounted on the vehicle and thereby drives and controls the wiper (Step S60). When the processing portion 252 determines that any raindrop does not adhere to the windshield 290, the processing portion 252 waits until light is applied from the light emitting element 210 again. When an electrical signal corresponding to the light is inputted from the light receiving elements 230, the processing portion 252 determines the presence or absence of a raindrop according to the input. Though unshown in FIG. 11, the processing portion 252 adds information for determining the drive speed of the wiper according to the inspection value to the determination signal. When an inspection value is larger than the threshold value, the quantity of raindrops adhering to the windshield 290 is increased with increase in the difference between the values. Therefore, the processing portion 252 adds a drive speed of the wiper in proportion to the difference between an inspection value and the threshold value to the determination signal.

The following will describe operational effects of the optical sensor 200 in the embodiment. As mentioned, the amounts of electric charges converted at the individual light receiving elements 230 are individually adjusted by the voltage regulating portion 251; the voltage levels of the respective electrical signals of the light receiving elements 230 are individually adjusted by the same. Therefore, in the embodiment, an electrical signal of a desired voltage level can be obtained from each light receiving element 230 just by causing the light emitting element 210 to emit light once, unlike a comparative configuration where an electrical signal of a desired voltage level is obtained from each light receiving element by individually adjusting the amount of light emission from the light emitting element in correspondence with the individual light receiving elements. As mentioned, the optical sensor 200 in the embodiment can obtain a desired electrical signal in a shorter time than in the comparative configuration. The optical sensor 200 enables to obtain the electrical signal of each light receiving element 230 regulated to a desired voltage level just by causing the light emitting element 210 to emit light once, unlike the comparative configuration.

The control portion 255 individually adjusts the non-driven time of a switch 254 corresponding to each light receiving element 230. Thus without any deposit adhering to the transparent board 290, the voltage levels of the respective electrical signals of the light receiving elements 230 are made identical with one another. Since light projected from the light emitting element 210 has directional characteristics, light reflected by the transparent board 290 and incident on each light receiving element 230 varies in amount. Thus, the light receiving elements 230 are different from one another in detection sensitivity. As mentioned, the control portion 255 individually adjusts the non-driven time of each switch 254 so that the respective detection sensitivities of the light receiving elements 230 are made identical with one another. This suppresses variation in the amount of electric charges converted at each light receiving element 230 and variation in detection sensitivity from one light receiving element 230 to another. The detection sensitivity for deposits is thereby enhanced.

The circuit unit 250 includes the light emission amount adjusting portion 253 that adjusts the amount of light emission from the light emitting element 210. This enables to determine the detection sensitivity of each light receiving element 230 more closely than in a configuration not providing the light emission amount adjusting portion 253.

One light emitting element 210 is provided. This reduces the physical size of the optical sensor 200 as compared with a configuration providing a plurality of light emitting elements 210.

The processing portion 252 determines that a deposit adheres to the transparent board 290 on occasions when: an inspection value obtained by subtracting the voltage level of the electrical signal of the light receiving elements 230 from the voltage level of the expected signal is larger than a threshold value. The surface of the transparent board 290 is not always clean; the amount of reflected light reflected by the transparent board 290 and incident on each light receiving element 230 is not always identical. When the surface of the transparent board 290 is not clean, the amount of light incident on the light receiving elements 230 can be reduced despite no deposit adhering to the transparent board 290. Therefore, a deposit can be erroneously detected in a configuration determining that a deposit adheres to the transparent board in cases that the voltage level of the electrical signal of each light receiving element is lower than a voltage level (i.e., expected voltage level) of the electrical signal outputted from the light receiving element when any deposit does not adhere to the transparent board. Therefore, as mentioned, it is determined that a deposit adheres to the transparent board 290 when an inspection value obtained by subtracting the voltage level of the electrical signal of the light receiving elements 230 from the voltage level of the expected signal is larger than the threshold value. This suppresses erroneous detection of a deposit.

The processing portion 252 determines that a deposit adheres to the transparent board 290 when the lowest one of the inspection values corresponding to the individual light receiving elements 230 is larger than a threshold value. A deposit adheres to the transparent board 290 at random; a reduced amount of light incident on each light receiving element 230 due to a deposit is random. Therefore, the inspection value corresponding to each light receiving element 230 is also random. However, when only whether or not any deposit adheres to the transparent board 290 is determined, the above-described determination is desirably executed. That is, whether or not any deposit adheres to the transparent board 290 is determined based on the lowest one that is expected to be most affected by a deposit among a plurality of the inspection values.

The above described a preferred embodiment of the present disclosure. The present disclosure is not limited to the embodiment and can be variously modified without departing from the subject matter of the present disclosure.

The embodiment explained an example providing the circuit unit 250 including the light emission amount adjusting portion 253. The circuit unit 250 need not include the light emission amount adjusting portion 253.

The embodiment explained an example providing the light emitting element 210 being LED. The light emitting element 210 is not limited to the example and anything that emits light may be adopted as appropriate.

The embodiment explained an example providing one light emitting element 210 in the wiring board 270. The number of light emitting elements 210 is not limited to the example and more than one is also acceptable.

The embodiment explained an example providing each light receiving element 230 being PD. The light receiving elements 230 are not limited to the example and anything that executes photoelectric conversion may be adopted as appropriate.

The embodiment explained an example providing nine light receiving elements 230 in the wiring board 270. The number of light receiving elements 230 is not limited to the example and any number is acceptable as long as the number is more than one.

The embodiment explained an example providing nine light receiving elements 230 in a matrix. The arrangement of the light receiving elements 230 is not limited to the example.

The embodiment explained an example in FIG. 9 including a switch 254, a light receiving element 230, and a resistor 256 to be connected in series in this order from a power supply to the ground while the midpoint potential between the light receiving element 230 and the resistor 256 provides the electrical signal of the light receiving element 230. Instead, a modification may be adopted as in FIG. 12. That is, the voltage regulating portion 251 includes a transfer transistor 257, a capacitor 258, a voltage conversion transistor 259, a reset transistor 260, a resistor 256, and switches 254a, 254b. A light receiving element 230 and the capacitor 258 are connected in parallel between a first power supply and the ground; the light receiving element 230 and the capacitor 258 are electrically connected with the first power supply through the transfer transistor 257 and the first switch 254a. One end of the first switch 254a is connected to the first power supply; the other end is connected to the control electrode of the transfer transistor 257. This configuration permits the voltage of the first power supply to be inputted to the control electrode of the transfer transistor 257 when the first switch 254a is brought into a driving state by the control portion 255. This voltage input permits the transfer transistor 257 to be brought into a driving state and permits the light receiving element 230 and the capacitor 258 to be electrically connected with each other. Electric charges obtained by photoelectric conversion at the light receiving element 230 are thereby transferred to the capacitor 258 through the transfer transistor 257; the electric charges are accumulated in the capacitor 258. A voltage corresponding to the accumulation of electric charges is produced at the capacitor 258; this voltage is inputted to the control electrode of the voltage conversion transistor 259. As in FIG. 12, the voltage conversion transistor 259 and the resistor 256 are connected in series from a second power supply to the ground; the midpoint potential between the transistor and the resistor is inputted to the processing portion 252 as the electrical signal of the light receiving element 230. As mentioned, a voltage corresponding to electric charges obtained by conversion at the light receiving element 230 is produced at the capacitor 258; this voltage is inputted to the control electrode of the voltage conversion transistor 259, fluctuating the driving state of the voltage conversion transistor 259 and the midpoint potential between the voltage conversion transistor 259 and the resistor 256. As in FIG. 12, the reset transistor 260 and the capacitor 258 are connected in series from the second power supply to the ground; the control electrode of the reset transistor 260 is electrically connected with the first power supply through the second switch 254b. Under this configuration, the voltage of the first power supply is inputted to the control electrode of the reset transistor 260 when the second switch 254b is brought into a driving state by the control portion 255. Then the capacitor 258 is electrically connected with the second power supply. This resets the electric charges corresponding to photoelectric conversion by the light receiving element 230, accumulated in the capacitor 258.

In the modification in FIG. 12, the first switch 254a is brought into a driving state and the second switch 254b is brought into a non-driving state when a voltage is outputted which corresponds to electric charges obtained by photoelectric conversion at the light receiving element 230. Thus, the transfer transistor 257 is brought into a driving state to transfer electric charges by conversion at the light receiving element 230 to the capacitor 258; the driving state of the voltage conversion transistor 259 is varied according to a voltage produced at the capacitor 258; and the midpoint potential between the voltage conversion transistor 259 and the resistor 256 is outputted to the processing portion 252. When electric charges obtained by photoelectric conversion are reset, the first switch 254a is brought into a non-driving state and the second switch 254b is brought into a driving state. The reset transistor 260 is thus brought into a driving state to electrically connect the capacitor 258 with the second power supply; the electric charges accumulated in the capacitor 258 are reset.

The embodiment explained an example providing the control portion 255 individually adjusting the non-driven time of each switch 254. Thus the voltage levels of the respective electrical signals of the light receiving elements 230 become equal to the voltage level of the expected signal. Without limited thereto, the control portion 255 only has to individually control the non-driven time of a switch 254 corresponding to each light receiving element 230 so that: when any deposit does not adhere to the transparent board 290, the voltage levels of the respective electrical signals of the light receiving elements 230 are made identical with one another.

In the embodiment, the processing portion 252 determines that a deposit adheres to the transparent board 290 when the lowest one of the inspection values respectively corresponding to the light receiving elements 230 is larger than a threshold value. Without limited thereto, the processing portion 252 only need detect any deposit adhering to the transparent board 290 based on increase/decrease of the electrical signals of the light receiving elements 230.

In the embodiment, the light emission amount adjusting portion 253 adjusts the amount of light emission from the light emitting element 210 by adjusting at least either of: the amount of current passed through the light emitting element 210 for a unit time according to the state of the surface of the transparent board 290; and the time of the energization. Instead, the light emission amount adjusting portion 253 may adjust the amount of current passed through the light emitting element 210 and the time of the energization based on output signals of: a humidity sensor, a temperature sensor, and a solar sensor in the vehicle.

Though not especially described in the embodiment, the nine light receiving elements 230 are electrically independent of one another. Instead, another configuration may be adopted which divides the plurality of light receiving elements 230 into a plurality of light receiving element groups; each light receiving element group includes a plurality of light receiving elements 230 that share a single output terminal. Here, the amounts of respective electric charges of the light receiving element groups are individually adjusted by the voltage regulating portion 251 and the voltage levels of resulting electrical signals are individually adjusted by the same.

Intending to reduce the physical size of the optical sensor 200 may provide a difficulty in setting the layout of wiring patterns connected to each light receiving element 230. The configuration may be thus adopted which includes the plurality of light receiving element groups, each of which shares a single output terminal. Light from the light emitting element 210, reflected by the transparent board 290 is detected by the plurality of light receiving element groups included in the plurality of light receiving elements.

While the present disclosure has been described with reference to embodiments thereof, it is to be understood that the disclosure is not limited to the embodiments and constructions. The present disclosure is intended to cover various modification and equivalent arrangements. In addition, while the various combinations and configurations, other combinations and configurations, including more, less or only a single element, are also within the spirit and scope of the present disclosure.

1. An optical sensor attached to a transparent board,
comprising:
a light emitting element that applies light to the transparent board that reflects the light;
a plurality of light receiving elements that receive the light reflected by the transparent board; and
a detection unit that detects an amount of rainfall based on output signals of the plurality of light receiving elements,
wherein:
the light emitting element applies light to one irradiation region in the transparent board;
the plurality of light receiving elements correspond to the one irradiation region;
the detection unit detects the amount of rainfall based on output signals of the plurality of light receiving elements corresponding to the one irradiation region; and
the plurality of light receiving elements are formed in a single semiconductor substrate.

2. The optical sensor according to claim 1,
wherein the detection unit includes a weighting portion that adds a weight to output signals of the plurality of light receiving elements, the weight corresponding to a distribution of intensity of light incident on each of the plurality of light receiving elements, to cause the plurality of light receiving elements to provide respective detection sensitivities to be close to one another in states where no deposit is on the transparent board.

3. The optical sensor according to claim 2,
wherein the weighting portion adds the weight to an output signal of a light receiving element low in intensity of incident light among the plurality of light receiving elements, to cause an intensity of the output signal of the light receiving element low in intensity of incident light to be close to an intensity of an output signal of a light receiving element high in intensity of incident light.

4. The optical sensor according to claim 3,
wherein the weighting portion adds the weight to each of the output signals of the plurality of light receiving elements to cause the output signals of the plurality of light receiving elements to provide respective intensities to be identical with one another.

5. The optical sensor according to claim 2,
wherein the detection unit includes
a comparison portion that compares each of the output signals of the plurality of light receiving elements weighted by the weighting portion with a threshold voltage and outputs a first signal when the output signal is lower than the threshold voltage and a second signal when the output signal is not lower than the threshold voltage,
a count portion that counts a counted number of either the first signal or the second signal outputted from the comparison portion, and
a rainfall amount detection portion that detects an amount of rainfall based on the counted number that is counted by the count portion.

6. The optical sensor according to claim 5, wherein:
the comparison portion includes a plurality of the threshold voltages different in value as the threshold voltage and outputs the first signal or the second signal resulting from sequential comparison of the different threshold voltages with each of the output signals of the plurality of light receiving elements to the count portion; and
the rainfall amount detection portion detects the amount of rainfall based on the counted number corresponding to each of the threshold voltages different in value.

7. The optical sensor according to claim 1,
wherein the detection unit is placed between the light emitting element and the plurality of light receiving elements.

8. The optical sensor according to claim 1, further comprising:
a lens that is provided on the transparent board, the lens adjusting an incident angle of light incident on the plurality of light receiving elements.

9. (canceled)

10. An optical sensor comprising:
a light emitting element that applies light to a transparent board that reflects the light;
a plurality of light receiving elements that
receive the light reflected by the transparent board, and
convert the received light into electrical signals;
a voltage regulating portion that regulates a voltage level of the electrical signal outputted from each of the light receiving elements;
a light emission adjusting portion that adjusts an amount of light emission from the light emitting element; and
a processing portion that processes an electrical signal outputted from each of the plurality of light receiving elements, wherein
each of the plurality of light receiving elements converts light into an electric charge and outputs a voltage corresponding to the electric charge as the electrical signal,
the voltage regulating portion individually regulates an amount of the electric charge converted at each of the plurality of light receiving elements and individually adjusts the voltage level of the electrical signal of each of the plurality of light receiving elements, and
when each of a plurality of inspection values obtained by subtracting the voltage level of the electrical signal of each of the plurality of light receiving elements from a voltage level of an electrical signal outputted from each of the plurality of light receiving elements under states where no deposit adheres to the transparent board is larger than a threshold value, the processing portion determines that a deposit adheres to the transparent board.

11. The optical sensor according to claim 10, wherein:
the voltage regulating portion includes
a switch that discharges electric charge accumulated in each of the plurality of light receiving elements; and
a control unit that controls drive of the switch; and
the control unit individually adjusts driven time and non-driven time of the switch corresponding to each of the plurality of light receiving elements, to cause the voltage levels of the respective electrical signals of the plurality of light receiving elements to be identical with one another under states where no deposit adheres to the transparent board.

12. The optical sensor according to claim 11,
wherein the control unit individually adjusts the driven time and the non-driven time of the switch corresponding to each of the light receiving elements to cause the voltage level of the electrical signal of each of the plurality of light receiving elements to be equal to a voltage level of an electrical signal expected to be outputted from each of the plurality of light receiving elements under states where no deposit adheres to the transparent board.

13. (canceled)

14. The optical sensor according to claim 10,
wherein the number of the light emitting element is one.

15. The optical sensor according to claim 10,
wherein:
the plurality of light receiving elements are divided into a plurality of light receiving element groups, each light receiving element group including a plurality of light receiving elements sharing a single output terminal; and
the voltage regulating portion adjusts an amount of electric charge of each light receiving element group, to adjust a voltage level of an electrical signal.

16. (canceled)

17. The optical sensor according to claim 10,
wherein when a lowest inspection value of the inspection values corresponding to the respective light receiving elements is larger than the threshold value, the processing portion determines that a deposit adheres to the transparent board.

18. The optical sensor according to claim 10,
wherein:
the deposit is a raindrop; and
the processing portion determines whether or not any raindrop adheres to the transparent board based on the electrical signal outputted from each of the plurality of light receiving elements and the threshold value.
